(19) United States
(12) Patent Application Publication
(10) Pub. No.: US 2013/0309985 A1
(43) Pub. Date: Nov. 21, 2013

(54) TRANSMISSION MODULE

(71) Applicant: MURATA MANUFACTURING CO., LTD., Nagaokakyo-shi (JP)

(72) Inventors: Kenji SAITO, Nagaokakyo-shi (JP); Shingo YANAGIHARA, Nagaokakyo-shi (JP); Tsuyoshi SATO, Nagaokakyo-shi (JP); Syunji YOSHIMI, Nagaokakyo-shi (JP); Kazuyuki WATANABE, Nagaokakyo-shi (JP)

(73) Assignee: MURATA MANUFACTURING CO., LTD., Nagaokakyo-shi (JP)

(21) Appl. No.: 13/950,576

(22) Filed: Jul. 25, 2013

Related U.S. Application Data
(63) Continuation of application No. PCT/JP2012/051495, filed on Jan. 25, 2012.

(30) Foreign Application Priority Data
Jan. 28, 2011 (JP) 2011-015891

(51) Int. Cl. H04B 15/00; H03F 3/193

(52) U.S. Cl. CPC H04B 15/00; H03F 3/193
USPC 455/114.3

(57) ABSTRACT

A multiband transmission module includes a power amplifier and a multiband isolator. An output end of the power amplifier is connected to a single input terminal of the multiband isolator. The multiband isolator includes a low-frequency individual isolator and a high-frequency individual isolator. Input ends of the individual isolators are connected to the single input terminal of the multiband isolator. Output ends of the individual isolators are respectively connected to a low-frequency output terminal and a high-frequency output terminal of the multiband isolator.

### BACKGROUND OF THE INVENTION

1. Field of the Invention

The present invention relates to transmission modules that amplify and output transmission signals, and more particularly relates to a multiband transmission module that can amplify and output transmission signals with a plurality of frequency bands.

2. Description of the Related Art

A radio communication module mounted on a cellular phone, etc., includes a transmission circuit that generates a transmission signal and outputs the transmission signal to an antenna, and a reception circuit that amplifies a signal received by the antenna. In particular, a radio communication module compatible with multiband is in demand, and its transmission circuit has to generate transmission signals with different frequencies and supply the generated signals to its antenna. Japanese Unexamined Patent Application Publication No. 2008-154201 discloses a transmission device including a transmission-signal generator that generates a plurality of types of transmission signals, a power amplifier (PA) that amplifies the transmission signals from the transmission-signal generator, and a switching element that switches the transmission signals output from the PA and outputs the transmission signals to duplexers respectively provided for the plurality of types of the transmission signals.

However, since the transmission device (the transmission circuit) disclosed in Japanese Unexamined Patent Application Publication No. 2008-154201 has a structure that switches the transmission signals amplified by the PA and outputs the transmission signals, a loss generated at the switching element may unnecessarily attenuate the transmission signals.

### SUMMARY OF THE INVENTION

Therefore, preferred embodiments of the present invention provide a multiband transmission module that prevents a loss from being generated by a switching element, amplifies a plurality of types of transmission signals, and outputs the signals with a low loss.

According to a preferred embodiment of the present invention, a transmission module that amplifies and outputs transmission signals includes a power amplifier and a multiband isolator. The power amplifier amplifies a plurality of transmission signals which use different frequency bands. The multiband isolator is connected to an output end of the power amplifier. The multiband isolator includes a single input terminal and output terminals respectively different for the transmission signals, and includes individual isolators respectively connected between the input terminal and the output terminals.

With this configuration, the transmission signal with each of the frequency bands output from the power amplifier passes through the isolator corresponding to the transmission signal and is output from the individual output terminal. Accordingly, a loss caused by a switching element is not generated unlike the configuration of related art.

A transmission module according to a preferred embodiment of the present invention may preferably further include a detector circuit arranged between the output end of the power amplifier and the input terminal of the multiband isolator.

With this configuration, since the detector circuit is included, a portion of an output from the power amplifier can be fed back, and the feedback can be used to perform control to stabilize the output of the power amplifier. In this case, the feedback for the plurality of transmission signals can be provided by the single detector circuit.

A transmission module according to a preferred embodiment of the present invention may preferably further include a detector circuit at the output end of the multiband isolator.

With this configuration, feedback control can be performed for each output transmission signal, and further, feedback control with regard to a loss caused by the isolator can be performed.

In a transmission module according to a preferred embodiment of the present invention, the detector circuit may be preferably a directional coupler including a transmission line electrode serving as a main line, the transmission line electrode connecting the output end of the power amplifier to the input terminal of the multiband isolator.

With this configuration, the detector circuit connected between the power amplifier and the multiband isolator uses the directional coupler. By using the directional coupler, the main line can also function as a matching circuit between the power amplifier and the multiband isolator. Accordingly, a loss can be restricted in transmission from the power amplifier to the multiband isolator.

In a transmission module according to a preferred embodiment of the present invention, the directional coupler may preferably perform an impedance matching function that matches an impedance at an input end of the directional coupler with respect to the power amplifier, and an impedance at the multiband isolator with respect to an output terminal of the directional coupler.

With this configuration, impedance matching between the power amplifier and the directional coupler, and impedance matching between the directional coupler and the multiband isolator can be properly performed. Accordingly, the respective transmission signals can be transmitted with a low loss.

In a transmission module according to a preferred embodiment of the present invention, the directional coupler may be preferably arranged to cause the impedance at the input end of the directional coupler with respect to the power amplifier to be lower than the impedance at the multiband isolator with respect to the output terminal of the directional coupler.

With this configuration, a specific example of impedance design for the direction coupler is provided. In general, a power amplifier has a low-output impedance. In particular, when a final-stage FET is set at a small value, an output impedance becomes low (for example, about 3Ω). In contrast, the multiband isolator is set at a high impedance (about 50Ω) with respect to the transmission signal. Hence, if impedance conversion is performed so that the power amplifier side of the directional coupler has a low impedance (for example, about 3Ω) and the multiband isolator side of the directional coupler has a high impedance (for example, about 25Ω), the transmission signals can be transmitted with a low loss. Also, since the power amplifier can be small, the transmission module on which the power amplifier is mounted can be small.

A transmission module according to a preferred embodiment of the present invention may further include the following configuration. The multiband isolator includes an individual isolator for a high frequency band and an individual isolator for a low frequency band. A low pass filter circuit may be provided between the input terminal of the multiband isolator and the individual isolator for the low frequency band, the low pass filter circuit using an inductor and a capacitor.

With this configuration, the low pass filter passes the low-frequency transmission signal and attenuates the high-frequency transmission signal, and performs impedance conversion on the low-frequency transmission signal. Accordingly, rapid impedance conversion only by the individual isolator is not performed, but stepwise impedance conversion by the low pass filter and the individual isolator is performed. Hence, the transmission signal with a low loss can be transmitted.

According to various preferred embodiments of the present invention, multiband transmission modules amplify a plurality of types of the transmission signals and output the transmission signals with a low loss.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a circuit configuration diagram of a communication module 1 including a transmission module 10 according to a first preferred embodiment of the present invention.

FIG. 2 is an external perspective view of the transmission module 10 according to the first preferred embodiment of the present invention.

FIG. 3 is a circuit configuration diagram of a transmission module 10A according to a second preferred embodiment of the present invention.

FIG. 4 is a circuit configuration diagram of a transmission module 10B according to a third preferred embodiment of the present invention.

FIG. 5 is a circuit configuration diagram of a transmission module 10C according to a fourth preferred embodiment of the present invention.

FIG. 6 is a circuit configuration diagram of a transmission module 10D according to a fifth preferred embodiment of the present invention.

### DETAILED DESCRIPTION OF THE PREFERRED EMBODIMENTS

A transmission module 10 according to a first preferred embodiment of the present invention is described with reference to the drawings. In this preferred embodiment, a communication signal of WCDMA 850 or a communication signal of WCDMA 900 is preferably used as a low-frequency communication signal, and a communication signal of WCDMA 1800 or a communication signal of WCDMA 1900 is preferably used as a high-frequency communication signal.

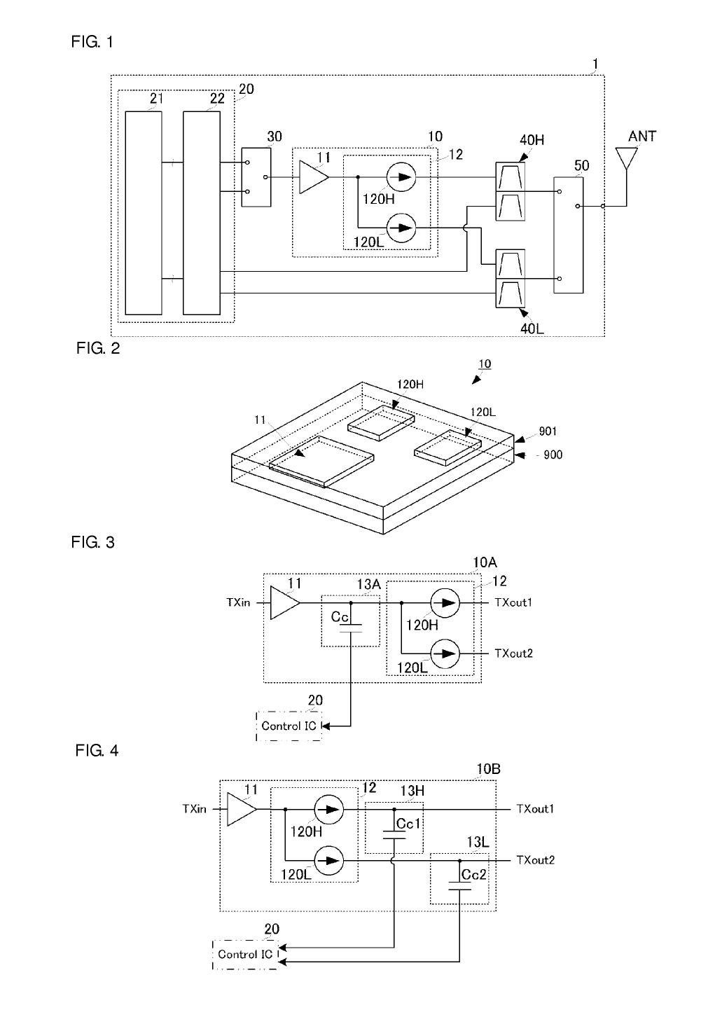

FIG. 1 is a circuit configuration diagram of a communication module 1 including the transmission module 10 according to the first preferred embodiment. FIG. 2 is an external perspective view of the transmission module 10 according to the first preferred embodiment. FIG. 2 illustrates only major mounted elements of the present preferred embodiment, but omits illustration of other mounted elements (for example, a switching element and a duplexer).

The transmission module 10 is included in the communication module 1 as shown in FIGS. 1 and 2. The communication module 1 includes the transmission module 10, a control IC 20, a switching element 30, duplexers 40H and 40L, and a switching element 50.

The control IC 20 includes a baseband IC 21 and a RFIC 22. The ICs are arranged and programmed to generate transmission signals with respective frequencies. More specifically, the ICs are arranged and programmed to generate a transmission signal for low-frequency communication (a first transmission signal) and a transmission signal for high-frequency communication (a second transmission signal). The control IC 20 is arranged and programmed to output and demodulate a reception signal for the low-frequency communication (a first reception signal) and a reception signal for the high-frequency communication (a second reception signal) output from the duplexers 40H and 40L. The control IC 20 also is arranged and programmed to perform switching control for the switching elements 30 and 50. The communication module 1 is preferably formed by mounting the transmission module 10 and other components on, for example, a motherboard such as a printed circuit board. The control IC 20 is provided by a mounted IC mounted on the motherboard.

The first transmission signal or the second transmission signal output from the RFIC 22 of the control IC 20 is output to the switching element 30. The switching element 30 outputs the first transmission signal or the second transmission signal to the transmission module 10 in accordance with the switching control.

The transmission module 10 includes a power amplifier and a multiband isolator 12. The power amplifier 11 is a multiband amplifier circuit that can amplify the first transmission signal and the second transmission signal to a level suitable for radio communication. As shown in FIG. 2, the power amplifier 11 is a mounted element mounted on a top surface of a stack 900.

The first transmission signal or the second transmission signal is input to an input end of the power amplifier 11, is amplified by the power amplifier 11, and is output from an output end of the power amplifier 11 to an input end of the multiband isolator.

The multiband isolator 12 preferably is a one-input two-output isolator, and includes an individual isolator 120L corresponding to the first transmission signal and an individual isolator 120H corresponding to the second transmission signal. A single input terminal of the multiband isolator 12 is connected to input ends of the individual isolators 120L and 120H. Two output terminals of the multiband isolator 12 are respectively connected to output ends of the individual isolators 120L and 120H.

The individual isolators 120L and 120H are each an isolator element including a core unit including a ferrite core, an electrode pattern arranged on the ferrite core, and a permanent magnet holding a core member including the ferrite core and the electrode pattern; and a peripheral circuit including components such as a capacitor and an inductor and arranged such that one end of the electrode pattern serves as an input end and the other end of the electrode pattern serves as an output end, the peripheral circuit being arranged between the core unit and the input end or the output end, as disclosed in, for example, Japanese Unexamined Patent Application Publication No. 2006-311455. In this case, the individual isolator 120L includes the core member that performs transmission with a low loss for only a frequency band of the first transmission signal, only from the input end to the output end. The individual isolator 120H includes the core member that performs transmission with a low loss for only a frequency band of the second transmission signal, only from the input end to the output end.

The peripheral circuit at the input end or the output end of each of the individual isolators 120L and 120H connects a transmission line to a ground potential, and has a matching function (not shown). Hence, the peripheral circuit performs impedance matching at the input end and the output end of each of the individual isolators 120L and 120H.

With this configuration, the individual isolators 120L and 120H can be small. As shown in FIG. 2, the individual isolators 120L and 120H are mounted on the stack 900. Hence, the shape of the multiband isolator 12 can be also small.

The multiband isolator 12 outputs the first transmission signal output from the power amplifier 11 through the individual isolator 120L to the duplexer 40L. The multiband isolator 12 outputs the second transmission signal output from the power amplifier 11 through the individual isolator 120H to the duplexer 40H.

With this configuration, even if the switching element is not provided directly downstream of the power amplifier 11 unlike the configuration of related art, the multiband transmission module 10 that outputs the first transmission signal to the duplexer 40L and outputs the second transmission signal to the duplexer 40H can be provided. Also, since the above-described configuration does not require a switching element, a loss caused by the switching element is not generated, and hence the multiband transmission module 10 with a low loss for any of the respective transmission signals can be provided.

The duplexer 40L is provided by, for example, a SAW duplexer, and includes a transmission SAW filter and a reception SAW filter. The transmission SAW filter of the duplexer 40L preferably is a filter having a pass band for a frequency band of the first transmission signal, and a stop band for other frequency bands containing a frequency band of the first reception signal. The reception SAW filter of the duplexer 40L preferably is a filter having a pass band for the frequency band of the first reception signal, and a stop band for other frequency bands containing the frequency band of the first transmission signal.

The first transmission signal input to the duplexer 40L is output through the transmission SAW filter to the switching element 50. The first reception signal from the switching element 50 passes through the reception SAW filter and is output to the RFIC 22 of the control IC 20.

The duplexer 40H preferably has a basic configuration similar to that of the duplexer 40L except for a pass band. The second transmission signal input to the duplexer 40H is output through the transmission SAW filter to the switching element 50. The second reception signal from the switching element 50 passes through the reception SAW filter and is output to the RFIC 22 of the control IC 20.

The switching element 50 includes individual terminals connected to the duplexers 40H and 40L and a common terminal connected to an external antenna ANT, and connects one of the individual terminals to the common terminal in accordance with the switching control. More specifically, if transmission or reception for the low-frequency communication is performed, the individual terminal for the low-frequency communication and the common terminal are connected so that the duplexer 40L and the antenna ANT are connected. If transmission or reception for the high-frequency communication is performed, the individual terminal for the high-frequency communication and the common terminal are connected so that the duplexer 40H and the antenna ANT are connected.

With the above-described circuit configuration, the communication module 1 is provided. The communication module 1 is partially described above; however, as shown in FIG. 2, the circuit shown in FIG. 1 is structurally provided by the stack 900 and the mounted elements. The stack 900 is preferably formed by stacking dielectric layers, which respectively have internal electrode patterns, by a predetermined number of layers. The internal electrode patterns and via-hole electrodes, which connect the layers, provide a circuit configuration except for the mounted elements. The mounted elements, which provide the control IC 20, the power amplifier 11, and the individual isolators 120L and 120H, are mounted on the top surface of the stack 900. Although not illustrated, the mounted elements, which provide the duplexers 40L and 40H and the switching elements 30 and 50, are also mounted. The top surface of the stack 900 with these mounted elements is covered with resin 901. The resin 901 protects the top surface and the mounted elements from the external environment.

As described above, by using the configuration of this preferred embodiment, the communication module 1 transmits and outputs any of the generated transmission signals with the respective frequency bands with a low loss. Further, by using the individual isolators 120L and 120H of this preferred embodiment, the small communication module 1 can be provided.

Next, a transmission module according to a second preferred embodiment of the present invention is described with reference to FIG. 3. FIG. 3 is a circuit configuration diagram of a transmission module 10A according to the second preferred embodiment. A communication module preferably has a basic configuration similar to that of the communication module of the first preferred embodiment except for the transmission module 10A. Hence, the explanation is omitted except for a necessary portion.

The transmission module 10A of the present preferred embodiment has a configuration in which a detector circuit 13A is connected between the output end of the power amplifier 11 and the input terminal of the multiband isolator 12.

The detector circuit 13A includes a capacitor Cc including one end connected to a transmission line electrode that connects the output end of the power amplifier 11 and the input terminal of the multiband isolator 12. The other end of the capacitor Cc is connected to the control IC 20.

With this configuration, a feedback signal at a level corresponding to the level of the transmission signal output from the power amplifier 11 is output to the control IC 20. The control IC 20 controls an input power level to the power amplifier 11 in accordance with the level of the feedback signal. Accordingly, the transmission signal at the stable level can be output from the power amplifier 11.

Further, with the configuration of the present preferred embodiment, the transmission signal at the stable level can be output by using the single detector circuit 13A for any of the first transmission signal and the second transmission signal. Accordingly, feedback control for the transmission signals with the plurality of frequencies can be executed almost without an increase in size of the communication module. In particular, if only the capacitor Cc as shown in FIG. 3 is included, and if the capacitor Cc is provided by inner-layer electrodes of the stack 900, the small communication module having the feedback control function can be provided.

Next, a transmission module according to a third preferred embodiment of the present invention is described with reference to FIG. 4. FIG. 4 is a circuit configuration diagram of a transmission module 10B according to the third preferred embodiment. A communication module preferably has a basic configuration similar to that of the communication module of the first preferred embodiment except for the transmission module 10B. Hence, the explanation is omitted except for a necessary portion.

In the transmission module 10B of the present preferred embodiment, detector circuits 13L and 13H are respectively connected to the individual isolators 120L and 120H.

The detector circuit 13L includes a capacitor Cc1. The capacitor Cc1 includes one end connected to a transmission line electrode that connects the output terminal of the individual isolator 120L to the output terminal for the low-frequency communication of the transmission module 10B. The other end of the capacitor Cc1 is connected to the control IC 20. The capacitor Cc1 has a capacitance set in accordance with the frequency band of the first transmission signal.

The detector circuit 13H includes a capacitor Cc2. The capacitor Cc2 includes one end connected to a transmission line electrode that connects the output terminal of the individual isolator 120H to the output terminal for the high-frequency communication of the transmission module 10B. The other end of the capacitor Cc2 is connected to the control IC 20. The capacitor Cc2 has a capacitance set in accordance with the frequency band of the second transmission signal.

With this configuration, feedback control for a gain of the power amplifier 11 is performed for each transmission signal, with regard to a loss caused by the multiband isolator 12.

Also, as shown in FIG. 4, if the detector circuits 13L and 13H only respectively include the capacitors Cc1 and Cc2, and if the capacitors Cc1 and Cc2 are provided by inner-layer electrodes of the stack 900, even though a detector circuit is added, the small communication module can be provided.

Next, a transmission module according to a fourth preferred embodiment of the present invention is described with reference to FIG. 5. FIG. 5 is a circuit configuration diagram of a transmission module 10C according to the fourth preferred embodiment. A transmission module preferably has a basic configuration similar to that of the transmission module of the second preferred embodiment except for a detector circuit 13C. Hence, the explanation is omitted except for a necessary portion.

The detector circuit 13C of this preferred embodiment preferably includes a directional coupler including a main line provided by a transmission line electrode that connects the output end of the power amplifier 11 to the input terminal of the multiband isolator 12, and a sub-line that is coupled to the main line. The sub-line includes one end that is connected to the control IC 20, and the other end that is terminated with a predetermined impedance. Even with this configuration, feedback control to the power amplifier 11 can be performed like the second preferred embodiment.

Also, for example, if the main line and the sub-line are defined by inner-layer electrode patterns of the stack, the communication module can be small.

Further, by using the configuration of the present preferred embodiment, the detector circuit 13C including the directional coupler can function as an impedance matching circuit, with an inductance or a capacitance generated in accordance with the length of the electrode of the main line or coupling between the main line and the sub-line.

Accordingly, an additional matching circuit that performs impedance matching between the power amplifier 11 and the multiband isolator 12 is not required. Hence, the small transmission module and the small communication module can be provided while a low-loss characteristic is maintained.

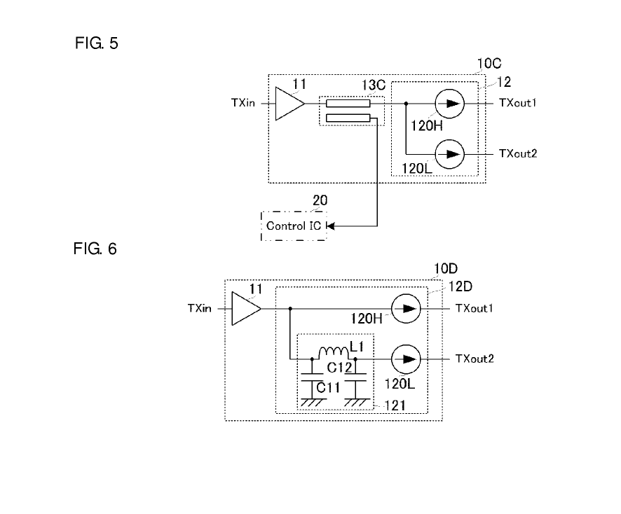

Next, a transmission module according to a fifth preferred embodiment of the present invention is described with reference to FIG. 6. FIG. 6 is a circuit configuration diagram of a transmission module 10D according to the fifth preferred embodiment. A communication module preferably has a basic configuration similar to that of the communication module of the first preferred embodiment except for the transmission module 10D. Hence, the explanation is omitted except for a necessary portion.

In the transmission module 10D of the present preferred embodiment, a configuration of a multiband isolator 12D differs from the configuration of the multiband isolator 12 of the first preferred embodiment.

In the multiband isolator 12D, a low pass filter (LPF) 121 is connected between a single input terminal of the multiband isolator 12D and the input end of the low-frequency individual isolator 120L.

The LPF 121 is preferably defined by a π-type circuit including an inductor L1 and capacitors C11 and C12. The inductor L1 is connected in series between the single input terminal of the multiband isolator 12D and the input end of the low-frequency individual isolator 120L. The capacitors C11 and C12 connect both ends of the inductor L1 to the ground.

The LPF 121 has a pass band for the frequency band of the first transmission signal, and has a characteristic that attenuates a high frequency band side of the pass band, the side which contains the frequency band of the second transmission signal, by properly setting element values of the inductor L1, and the capacitors C11 and C12. Accordingly, only the first transmission signal is input to the individual isolator 120L, but the second transmission signal is not input to the individual isolator 120L.

The LPF 121 also functions as an impedance matching circuit by properly setting the element values of the inductor L1, and the capacitors C11 and C12. In this case, the LPF 121 is set so that the output side of the power amplifier 11 (the input terminal of the multiband isolator 12) has a relatively low impedance (for example, about 5Ω) and the input side of the individual isolator 120L has a relatively high impedance (for example, about 25Ω). With this configuration, since impedance conversion is executed stepwise, by a plurality of steps of the LPF 121 and the individual isolator 120L for the first transmission signal, an impedance conversion loss is significantly reduced. Accordingly, the transmission module and the communication module with a low loss can be provided.

While the above-described preferred embodiments have individual feature configurations, even if the configurations of the preferred embodiments are combined, advantageous effects similar to those of the preferred embodiments can be provided.

Also, in the above-described preferred embodiments, the communication signal of WCDMA 850 or the communication signal of WCDMA 900 is preferably used as the low-frequency communication signal, and the communication signal of WCDMA 1800 or the communication signal of WCDMA 1900 is preferably used as the high-frequency communication signal, for example. However, a configuration in which the low-frequency communication signal uses WCDMA 850 and the high-frequency communication signal uses WCDMA 950 may be used, for example. It is to be noted that the above-described configuration is more effective as the frequency band of the low-frequency communication signal and the frequency band of the high-frequency communication signal are separated by a larger value. Also, the above-described configuration can be applied to not only the WCDMA-based communication signals, but also other communication signals.

Also, in the above-described preferred embodiments, the one-input two-output multiband isolator is described as an example. However, the above-described configuration can be applied to one-input N-output multiband isolator when N is an integer equal to or larger than 2.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. (canceled)

2. A transmission module, comprising:
a power amplifier that amplifies a plurality of transmission signals which use different frequency bands; and
a multiband isolator connected to an output end of the power amplifier, including a single input terminal and a plurality of output terminals respectively provided for each of the plurality of transmission signals, and including individual isolators respectively connected between the single input terminal and the plurality of output terminals.

3. The transmission module according to claim 2, further comprising a detector circuit arranged between the output end of the power amplifier and the input terminal of the multiband isolator.

4. The transmission module according to claim 2, further comprising detector circuits respectively provided at each of the output terminals of the multiband isolator.

5. The transmission module according to claim 3, wherein the detector circuit includes a directional coupler including a transmission line electrode defining a main line, the transmission line electrode connecting the output end of the power amplifier to the input terminal of the multiband isolator.

6. The transmission module according to claim 5, wherein the directional coupler performs an impedance matching function to match an impedance at an input end of the directional coupler with respect to the power amplifier, and an impedance at the multiband isolator with respect to an output terminal of the directional coupler.

7. The transmission module according to claim 6, wherein the directional coupler is arranged to cause the impedance at the input end of the directional coupler with respect to the power amplifier to be lower than the impedance at the multiband isolator with respect to the output terminal of the directional coupler.

8. The transmission module according to claim 2, wherein
the multiband isolator includes an individual isolator for a high frequency band and an individual isolator for a low frequency band; and
the transmission module further comprises a low pass filter circuit connected between the single input terminal of the multiband isolator and the individual isolator for the low frequency band, the low pass filter circuit including an inductor and a capacitor.

9. The transmission module according to claim 2, wherein the different frequency bands include at least one of WDMA 850, WCDMA 900, WCDMA 1800, and WCDMA 1900.

10. The transmission module according to claim 2, wherein
the plurality of transmission signals include a first transmission signal and a second transmission signal having a frequency band higher than that of the first transmission signal;
the individual isolators include a first isolator for the first transmission signal and a second isolator for the second transmission signal;
the single input terminal of the multiband isolator is connected to input ends of the first and second isolators; and
two of the output terminals of the multiband isolator are connected to output ends of the first and second isolators.

11. The transmission module according to claim 10, wherein each of the first and second isolators includes a ferrite core, an electrode pattern on the ferrite core and a permanent magnet holding the ferrite core and the electrode pattern.

12. The transmission module according to claim 11, wherein each of the first and second isolators includes a peripheral circuit that is provided at an input end or an output end thereof, connects a transmission line to a ground potential, and is arranged to perform a matching function.

13. The transmission module according to claim 3, wherein the detector circuit includes a capacitor including a first end connected to a transmission line electrode that connects the output end of power amplifier to the multiband isolator and a second end connected to a control IC.

14. The transmission module according to claim 4, wherein each of the detector circuits includes a capacitor including a first end connected to a transmission line electrode that connects the output end of power amplifier to the multiband isolator and a second end connected to a control IC.

15. The transmission module according to claim 8, wherein the low pass filter circuit is a π-type circuit and is connected in series between the single input terminal of the multiband isolator and the individual isolator for the low frequency band.

16. The transmission module according to claim 8, wherein the low pass filter circuit defines an impedance matching circuit.

17. A communication module comprising:
the transmission module according to claim 2;
a control IC;
a first switching element;
a second switching element; and
a plurality of duplexers.

18. The communication module according to claim 17, wherein the control IC includes a baseband IC and a RFIC arranged to generate the transmission signals.

19. The communication module according to claim 17, wherein the control IC is programmed to output and demodulate a reception signal for low-frequency communication and a reception signal for a high-frequency communication output from the duplexers.

20. The communication module according to claim 17, wherein the control IC is programmed to perform switching control for the first and second switching elements.

21. The communication module according to claim 17, wherein the duplexers include a transmission SAW filter and a reception SAW filter.
